(19) United States
(12) Patent Application Publication
(10) Pub. No.: US 2010/0053407 A1
(43) Pub. Date: Mar. 4, 2010

(54) Wafer level compliant packages for rear-face illuminated solid state image sensors

(75) Inventors: Richard Dewitt Crisp, Hornitos, CA (US); Belgacem Haba, Saratoga, CA (US); Vage Oganesian, Palo Alto, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 12/583,830

(22) Filed: Aug. 26, 2009

Related U.S. Application Data
(63) Continuation-in-part of application No. 12/393,233, filed on Feb. 26, 2009.
(60) Provisional application No. 61/067,209, filed on Feb. 26, 2008.

(51) Int. Cl. H04N 5/335; H01L 31/18

(52) U.S. Cl. 348/311; 438/65; 257/E31.097; 257/E31.11; 438/66; 348/E05.091

(57) ABSTRACT

A solid state image sensor includes a microelectronic element having a front face and a rear face remote from the front face, the rear face having a recess extending towards the front surface. A plurality of light sensing elements may be disposed adjacent to the front face so as to receive light through the part of the rear face within the recess. A solid state image sensor can include a microelectronic element, e.g., a semiconductor chip, having a front face and a rear face remote from the front face, a plurality of light sensing elements disposed adjacent to the front face, the light sensing elements being arranged to receive light through the rear face. A packaging structure, which can include a compliant layer, can be attached to a front surface of the microelectronic element. Electrically conductive package contacts may directly overlie the light sensing elements and the front face and be connected to chip contacts at the front face through openings in an insulating packaging layer overlying the front face.

### CROSS-REFERENCE TO RELATED APPLICATIONS

This application is a continuation-in-part of U.S. patent application Ser. No. 12/393,233 filed Feb. 26, 2009′. Said application claims the benefit of the filing date of U.S. Provisional Patent Application No. 61/067,209 filed Feb. 26, 2008, the disclosure of which is hereby incorporated herein by reference.

### BACKGROUND OF THE INVENTION

The subject matter shown and described in the present application relates to microelectronic image sensors and methods of fabricating, e.g., microelectronic image sensors.

Solid state image sensors, e.g. charge-coupled devices, (“CCD”) arrays, have a myriad of applications. For instance, they may be used to capture images in digital cameras, camcorders, cameras of cell phones and the like. One or more light-sensing elements on a chip, along with the necessary electronics are used to capture a “pixel” or a picture element, a basic unit of an image.

Improvements can be made to the structure of solid state image sensors and the processes used to fabricate them.

### SUMMARY OF THE INVENTION

In accordance with one embodiment, a solid state image sensor can include a microelectronic element having a front face and a rear face remote from the front face. The rear face can have a surface a first distance from the front surface in a direction normal to the front surface. A plurality of light sensing elements may be disposed adjacent to the front face and be aligned with the surface of the rear face so as to receive light through that surface.

In accordance with one embodiment, a solid state image sensor can include a microelectronic element having a front face, a plurality of chip contacts at the front face, and a rear face remote from the front face. A plurality of light sensing elements can be disposed adjacent to the front face, and may be conductively connected with the chip contacts. The light sensing elements may be arranged to receive light through the rear face. An insulating packaging layer can overlie and be attached to the front face and can include a compliant layer. Electrically conductive package contacts can directly overlie the front face and the light sensing elements. Conductors can extend within openings in the packaging layer from the chip contacts to the package contacts. The package contents, in turn, can be bonded to terminals of a circuit panel, such that the package contacts are subject to external loads applied by the terminals of the circuit panel. With the package contacts disposed on the compliant layer, the package contacts may be movable with respect to the chip contacts under external loads applied to the package contacts, For example, differential thermal expansion between a circuit panel and the chip can cause the terminals of the circuit panel to apply loads to the package contacts, which in turn, can cause the package contacts to move relative to the chip or the chip contacts.

The light sensing elements can include active semiconductor devices disposed adjacent to the front face. The conductors can include vertical interconnects in conductive communication with the active semiconductor devices and the package contacts.

In one embodiment, chip contacts can be exposed within the openings. The image sensor may include leads extending along interior surfaces of the openings which conductively connect the chip contacts with the package contacts. Each lead may cover an entire exposed interior surface of each opening or less than an entire exposed interior surface of each opening.

In one embodiment, each lead may extend along only a portion of an interior wall of each opening. For example, a second portion of the wall of the vertical interconnect remote from the first portion can remain uncovered by the lead.

In one embodiment, the light sensing elements can be disposed in a first region of the microelectronic element and the chip contacts can be disposed in a second region laterally adjacent to the first region, wherein the leads extend from the chip contacts to locations overlying the first region. The second region can be disposed between the first region and an edge of the microelectronic element.

The package contacts may be spaced farther apart than the chip contacts. The chip contacts may be disposed in at least a first direction along the front surface. The chip contacts may have a first pitch in the first direction and the package contacts may have a second pitch in the first direction. In one embodiment, the second pitch can be substantially greater than the first pitch.

In a particular embodiment, the package contacts can include one or the other of conductive masses and lands, or both. In such embodiment, the lands may be wettable by a fusible metal.

The image sensor may include a cover slip adjacent to the rear face. The image sensor may include an integrated stack lens disposed adjacent to the rear face.

In yet another embodiment of the present invention, a method of packaging a microelectronic image sensor includes (a) recessing portions of a rear surface of a device wafer, the portions being aligned with a plurality of light sensing elements adjacent to a front surface of the device wafer, (b) forming package contacts conductively interconnected with chip contacts exposed at the front surface, (c) assembling the device wafer with a light transmissive structure overlying the rear surface, and (d) severing the device wafer into individual packaged chips, each containing light sensing elements arranged to receive light through at least one of the recessed portions.

### BRIEF DESCRIPTION OF THE DRAWINGS

FIGS. 1A, 1B, 1C and 1D illustrate a method of fabricating a rear-face illuminated image sensor, according to an embodiment of the present invention.

FIG. 2A is sectional view illustrating a packaged back side illuminated image sensor according to an embodiment of the present invention.

FIG. 2B is sectional view illustrating a packaged back side illuminated image sensor according to a variation of the embodiment shown in FIG. 2A.

FIGS. 3A, 3B, 3C, 3D, 3E, 3F, 3G, 3H, 3I, 3J and 3K illustrate a process for packaging rear face-illuminated image sensor dies according to another embodiment of the present invention.

FIG. 4A is a partial sectional view illustrating a packaged image sensor die according to the method illustrated in FIGS. 3A-3K.

FIG. 4B is a sectional view illustrating a variation of the packaged sensor die shown in FIG. 4A.

FIG. 4C is a sectional view illustrating another variation of the packaged sensor die shown in FIG. 4A.

FIG. 5 is a top plan view of a packaged image sensor according to the method illustrated in FIGS. 3A-3K.

FIGS. 6A, 6B, 6C, 6D, 6E, 6F, 6G, 6H, 6I, 6J, and 6K are partial sectional views illustrating stages in a method of fabricating packaged image sensor dies in accordance with an embodiment of the invention.

FIG. 6L is a perspective view illustrating a packaged image sensor die in accordance with an embodiment of the invention.

### DETAILED DESCRIPTION

In an embodiment of the present invention, a wafer level package assembly is disclosed having a backside illuminated image sensor. U.S. Pat. No. 6,646,289, which is hereby incorporated by reference, discloses integrated circuit devices employing a thin silicon substrate. Optronic components are formed on a surface facing away from a corresponding transparent protective layer.

As discussed in the '289 patent, the thinness of the silicon allows for the optronic components to be exposed to light impinging via the transparent protective layer. Color filters may be formed on an inner surface of the protective layer. Further, an array of microlenses may also be disposed on an inner surface of the protective layer.

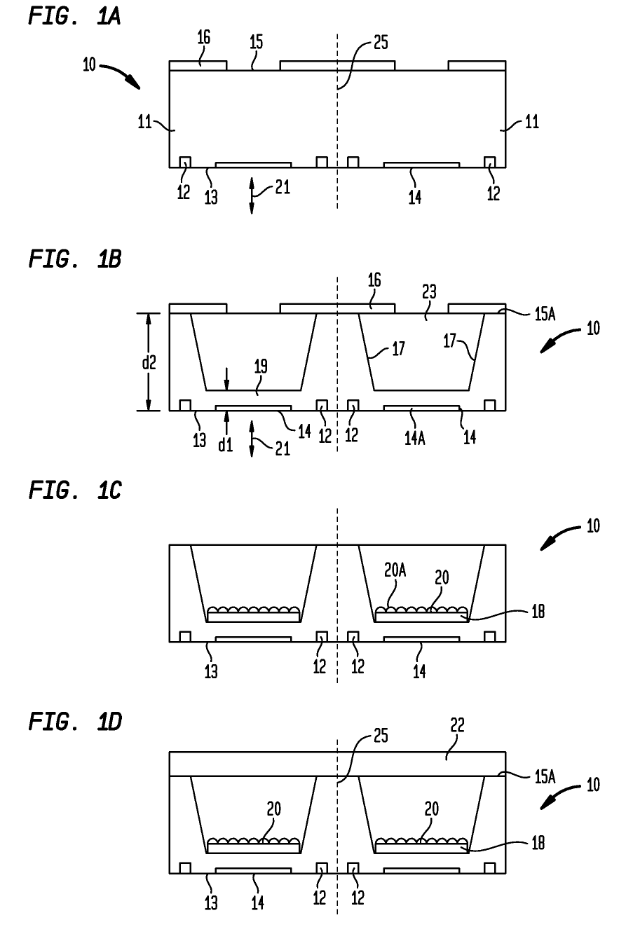

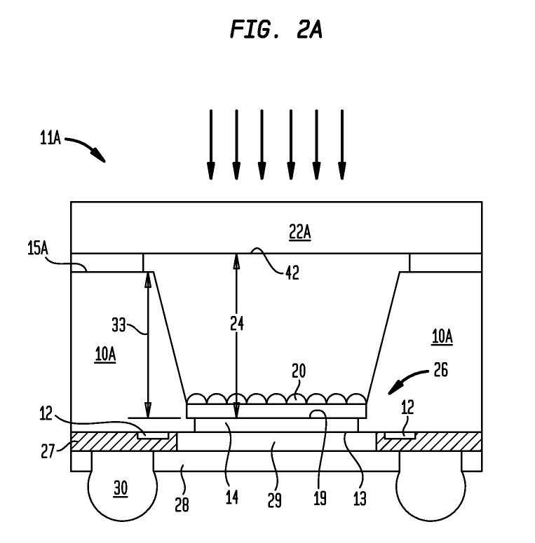

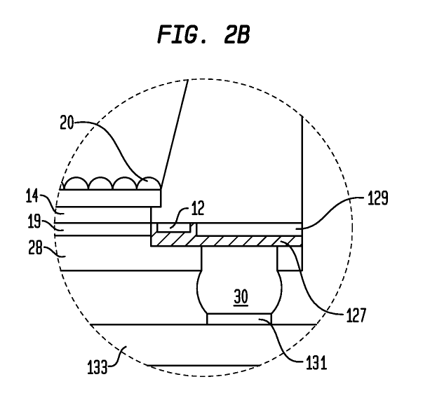

A method of fabricating a rear-face illuminated image sensor will now be described with reference to sectional views illustrating respective stages of fabrication in FIGS. 1A through 2. As illustrated in FIG. 1A, in a preliminary stage of fabrication, a device wafer 10 is shown with two adjoining regions 11 therein. A dicing lane 25 separates the regions 11, the dicing lane being the location along which the regions will be severed from each other at a later stage of fabrication. The device wafer 10 includes an active semiconductor layer or region which can consist essentially of silicon. Alternatively, the wafer may include other semiconductor materials such as for example, germanium (Ge), carbon (C), alloys or combinations of silicon with such material or one or more III-V compound semiconductor materials, each being a compound of a Group III element with a Group V element of the periodic table. Each region of the wafer has a front surface 13 at which bond pads 12 are exposed. The bond pads 12 typically overlie a dielectric layer disposed at the wafer front surface 13, such dielectric layer which may be referred to as a “passivation layer”.

As used in this disclosure, terms such as “top”, “bottom”, “upward” or “upwardly” and “downward” or “downwardly” refer to the frame of reference of the microelectronic element, e.g., semiconductor wafer or chip, or an assembly or unit which incorporates such wafer or chip. These terms do not refer to the normal gravitational frame of reference. For ease of reference, directions are stated in this disclosure with reference to a “top” or “front”, i.e., contact-bearing surface 13 of a semiconductor wafer or chip 10A. Generally, directions referred to as “upward” or “rising from” shall refer to the direction orthogonal and away from the chip top surface 13. Directions referred to as “downward” shall refer to the directions orthogonal to the chip top surface 13 and opposite the upward direction. A “vertical” direction shall refer to a direction orthogonal to the chip top surface. The term “above” a reference point shall refer to a point upward of the reference point, and the term “below” a reference point shall refer to a point downward of the reference point. The “top” of any individual element shall refer to the point or points of that element which extend furthest in the upward direction, and the term “bottom” of any element shall refer to the point or points of that element which extend furthest in the downward direction.

As used in this disclosure, a statement that an electrically conductive structure is “exposed at” a surface of a dielectric structure indicates that the electrically conductive structure is available for contact with a theoretical point moving in a direction perpendicular to the surface of the dielectric structure toward the surface of the dielectric structure from outside the dielectric structure. Thus, a terminal or other conductive structure which is exposed at a surface of a dielectric structure may project from such surface; may be flush with such surface; or may be recessed relative to such surface and exposed through a hole or depression in the dielectric.

As seen in FIG. 1A, each region 11 of the wafer typically includes one or more die attached to other such regions 11 at dicing lanes 25. Each region 11 includes an image sensor 14 adjacent to the front surface 13, the image sensor including a plurality of light-sensing elements typically arranged in an array for capturing an image cast thereon via light in directions 21 normal to the front surface. In one example, the image sensor can be a charge-coupled device (“CCD”) array. In another example, the image sensor can be a complementary metal oxide semiconductor (“CMOS”) device array.

Photolithography may be used to form mask patterns 16 overlying a rear surface 15 of the wafer, after which the wafer 10 may be etched from a rear surface 15 thereof using wet or dry etching as desired, as shown in FIG. 1B. Such etching forms recesses 23 in the rear surface 15 which extend inwardly from an outer surface 15A to an inner surface 19. The outer surface 15A is disposed at a greater distance (d2) from the front surface than the distance (d1) between the inner surface 19 and the front surface 13. The inner surface 19 is disposed at a distance d1 in a normal direction 21 to the front surface which is relatively close, i.e., at a distance which can range from a few microns up to about 20 microns. Thus, the thickness of the wafer 10 at the inner surface is defined by the distance d1. In an embodiment in which the device wafer 10 consists essentially of silicon, the distance between the front surface 13 and the inner surface 19 is necessarily small. The imaging light which strikes the light sensing elements 14A of the image sensor 14 passes through the inner surface 19 before interacting with the light sensing elements 14A within the thickness d1 of the wafer.

In addition, the transmissivity of the semiconductor material to light, especially silicon, can be limited. The distance d2 can be the same as the maximum thickness of the wafer in the normal direction 21. In an exemplary embodiment, the distance d2 and the maximum thickness of the device wafer 10 can range from about 50 microns to several hundred microns.

An anti-reflective coating (not specifically shown in FIG. 1B) may then be formed which overlies at least the inner surface 19 of the wafer within the recesses 23. The anti-reflective coating can help reduce the amount of light reflected back from the inner surface of the wafer and improve contrast ratio. Color filters 18 may then be formed or laminated to the wafer 10 to overlie the inner surface 19 within the recesses 23, as shown in FIG. 1C. The color filters 18 can be used to separate wavelengths of light arriving thereto through the color filters towards the inner surface 19 into different ranges of wavelengths that correspond to different ranges of color. Through use of a variety of different color filters each aligned with particular light-sensing elements of the image sensor, each color filter and light-sensing element can be used to sense only a limited predefined range of wavelengths corresponding to a particular range of colors. In such way, an array of undifferentiated light-sensing elements can be used with an appropriate combination of color filters geared to transmitting different colors to permit many different combinations of colors to be detected.

Sets of microlenses 20 may then be formed which overlie an exposed surface of the array of color filters 28. The microlenses 20 include tiny bumps of refractive material arranged in an array which help to focus light on one or more picture elements (“pixels”) of the imaging sensor. Each pixel typically is defined by an array of light-sensing elements, such that the light which arrives at the exposed surface 20A of each microlens is directed primarily onto one or more corresponding pixels.

As further illustrated in FIG. 1D, the inner surfaces 19 of the wafer 10 with the filters and microlenses thereon may be encapsulated by a lid wafer 22 as shown in FIG. 1D. The lid wafer 22 is at least partially transmissive to wavelengths of interest to the light-sensing elements incorporated in the image sensor. Thus, the lid wafer 22 may be transparent at such wavelengths, such as, for example, a lid wafer which consists essentially of one more various types of glass, or the lid wafer 22 may be transmissive with respect to only some wavelengths. Thus, the lid wafer 22 may include inorganic or organic materials, or a combination thereof.

After mounting the lid wafer 22 to the device wafer 10, the wafer may then be severed along the dicing lanes 25 into individual regions or dies 10A (FIG. 2A) to form individually packaged dies 11A each having a lid 22A attached to a rear surface of an individual die 10A thereof. For example, the assembly including the lid wafer 22 and the device wafer 10 can be severed by sawing through the lid wafer 22 and the device wafer 10 or the assembly can be severed by sawing the lid wafer 22 and scribing and breaking the device wafer 10 along the dicing lanes 25.

In an alternative embodiment, the device wafer 10 is not assembled with an intact lid wafer 22 in a wafer level assembly process. Rather, individual lids 22A can be mounted to the outer surfaces 15A of individual regions 11 of the intact device wafer 10, such as via pick-and-place techniques. Then, the device wafer 10 with the individual lids mounted thereon is severed into individual chips, each having an attached lid. In another alternative embodiment, an individual lid 22A can be mounted to an individual die 10A after the device wafer 10 has been singulated into individual dies.

As also illustrated in FIG. 2A, processing is performed at the front surface 13 of the die 10A in forming the packaged die 11A while the die remains attached to the device wafer. In an exemplary embodiment, bond pad extensions 27 are formed which extend along the front surface 13 in a lateral direction outward from original contacts 12, e.g., from the bond pads of the die 10A. The bond pads can be formed, for example, by selectively electroplating a metal onto a metal pattern defined previously, such as via sputtering or electroless plating and photolithography. Dielectric regions 29 may be disposed between the bond pad extensions, as illustrated in FIG. 2. The bond pad extensions 27 can include multiple features such as traces and interconnection pads which serve as contacts for the packaged die 11A.

Solder bumps 30 or other raised conductive features can be formed which extend from the bond pad extensions 27 in a direction downwardly away from the front surface 13. For example, the conductive features can include solder balls 30 attached to the extensions 27 in form of a ball grid array (“BGA”) or other arrangement. A solder mask or other dielectric layer 28 overlying the front surface 13 can avoid solder or other fusible metal used to mount the packaged die 11A from flowing in directions along the front surface of the packaged die 11A. The dielectric layer 28 may form a layer which encapsulates the original contacts 12 and the image sensor 14 at the front surface 13. The dielectric layer 28 or solder mask can be a photoimageable layer which can be deposited in liquid form by a spin-on or spray-on technique, followed by photolithographic patterning to form openings exposing at least portions of the pads 27 to which the.

It is to be noted that, in one embodiment, the above-described packaging processes (FIG. 2A) performed relative to the front surface 13 of the die can be performed prior to severing the assembly into individual packaged dies. In a particular embodiment, the above-described processes (FIG. 2) can be performed prior to some or all of the process steps described above with respect to FIGS. 1A through 1D.

FIG. 2A is a schematic illustration of a cross section of a packaged back side illuminated image sensor fabricated according to the method illustrated in FIGS. 1A-D. Here, a pixel 26 is illustrated adjacent the image sensor 14. Also the packaged sensor has a dielectric layer 28 and solder bumps 30. Further, this figure illustrates profiled silicon etching from the backside of the wafer. The glass wafer 22 can be provided on a wafer level prior to the dicing step as previously mentioned. The dielectric 28 can also be provided on a wafer level prior to the dicing step to singulate the dies.

The rear face illuminated configuration of the packaged die 11A achieves a standoff height 24 between the image sensor 14 and the inner surface 42 of the lid 22A. As seen in FIG. 2A, the standoff height 24 includes a portion of the thickness of the die. Specifically, the standoff height 24 includes a thickness 33 of the die between the outer surface 15A and the inner surface 19. An advantageous arrangement is achieved because the standoff height 24 is provided in the same direction as the thickness of the die 10A, rather than being in addition to the die thickness as it is in packages with lids mounted above the front surface. As a result, greater standoff height can be achieved than in some conventional front-face illuminated dies in which the total thickness of the package is limited, a result which may lead to improvements in cost, processing or the thickness of the package.

Another advantage is that the foregoing-described processes for forming packaged dies can be performed without requiring a handler wafer to be mounted to the device wafer during such processing. Still another advantage is that, with the recesses being made in the rear surface in alignment with the image sensors, processes such as grinding or polishing may not need to be performed to reduce the total thickness of the device wafer 10. Still another advantage is the ability to use wafer-level chip-scale packaging technology to form the packaged dies by the above-described processes.

In a variation (FIG. 2B) of the above-described embodiment, a compliant dielectric layer 129 can be provided between the front surface 13 of the chip and pads 127 of the package. As further seen in FIG. 2B, solder bumps 30 or other conductive features can extend from the pads 127. Alternatively, the pads 127 can be exposed at a surface of solder resist layer 28, for interconnection with terminals 131 of a circuit panel 133. The circuit panel can have a variety of structures and compositions, among which are BT (“bismaleimide triazine”) resin, FR-4, polyimide, etc. In a particular example, the circuit panel can have an epoxy-glass composition, of which FR-4 is a common example.

A compliant layer can reduce stresses placed on the pads 127 and solder bumps by allowing the pads 127 and bumps 30 thereon to move relative to the surface 19 of the chip under the influence of external loads applied to the bumps 30, such as through their connections with terminals 131 of a circuit panel. The chip 14 and the circuit panel 133 can have different linear coefficients of thermal expansion (“CTE”). For example, a chip consisting essentially of silicon has a CTE of about 3 ppm/° K, whereas an epoxy-glass printed circuit board of type FR-4 can have a CTE of about 10-15 ppm/° K. The compliant layer can reduce stresses that result from differential thermal expansion between the chip 14 and the circuit panel 133. For example, the compliant layer can reduce stresses that result from the chip 14 heating up to an operating temperature, given the difference in CTE between the chip and the circuit panel, by allowing the package contacts 127 to move relative to the chip contacts 12 under the influence of the loads applied from the circuit panel terminals 131.

The compliant layer 129 can be made of various materials such as, but not limited to, silicone, polyimide, flexibilized epoxy, liquid crystal polymer material, etc. The compliant layer can be a photoimageable or a non-photoimageable layer. In a particular embodiment, the compliant layer can be relatively thin. For example, the compliant layer can have a thickness ranging from 10 micrometers (microns or μm) and up.

In a particular embodiment, the temperature at which the compliant layer is curable should be higher than the temperature at which subsequent processes are performed. For example, the temperature required for curing the microlens array 20 may be between 100° C. and 250° C., or more typically between 150° C. and 200° C. In practice, the actual curing temperature or temperature range may depend upon a number of variables, such as the particular material used, the desired lens shape, etc. In one example, when formed prior to the microlens array, the compliant layer 129 can have a glass transition temperature T_{g} which is higher than the temperature at which the microlens array is fabricated.

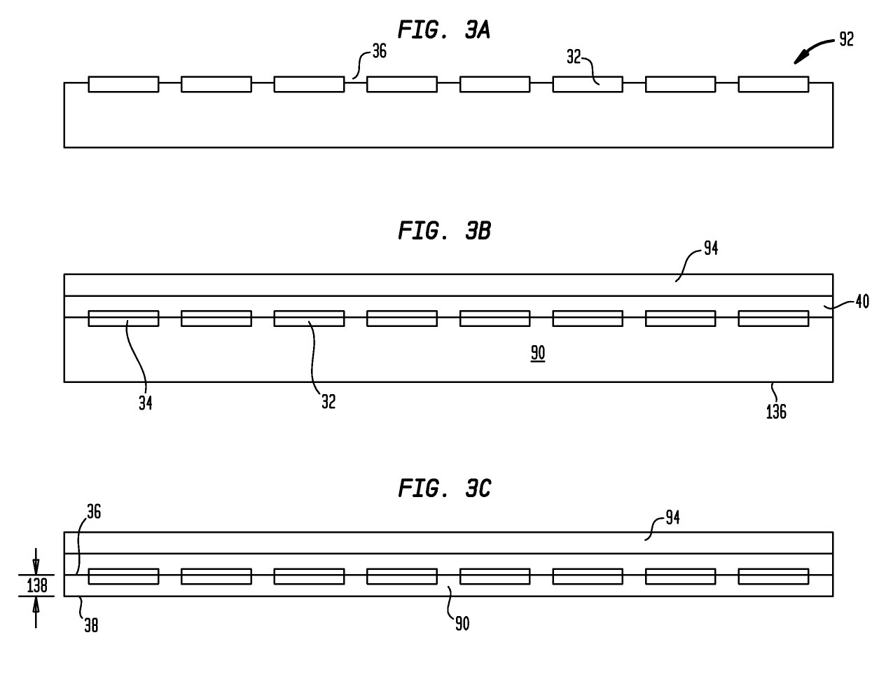

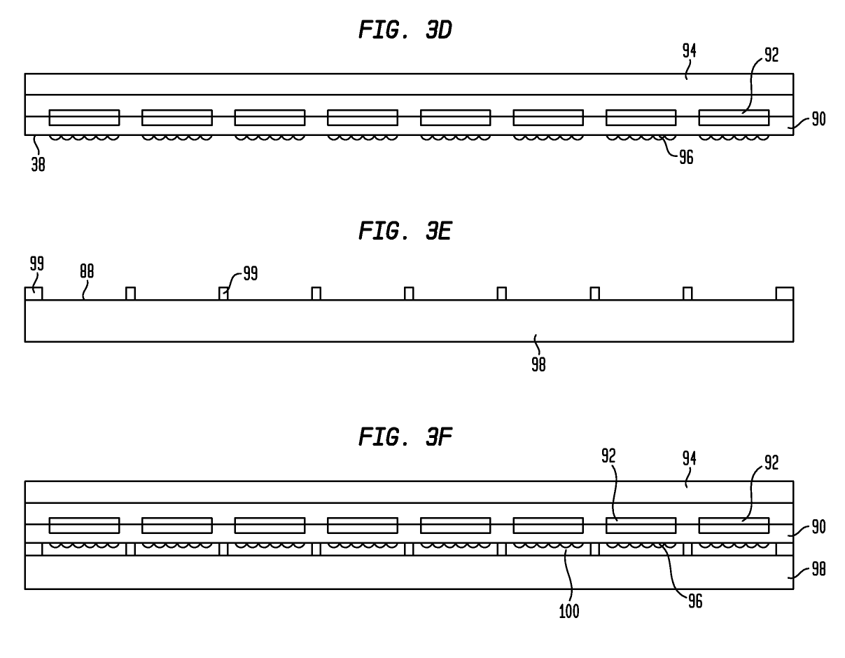

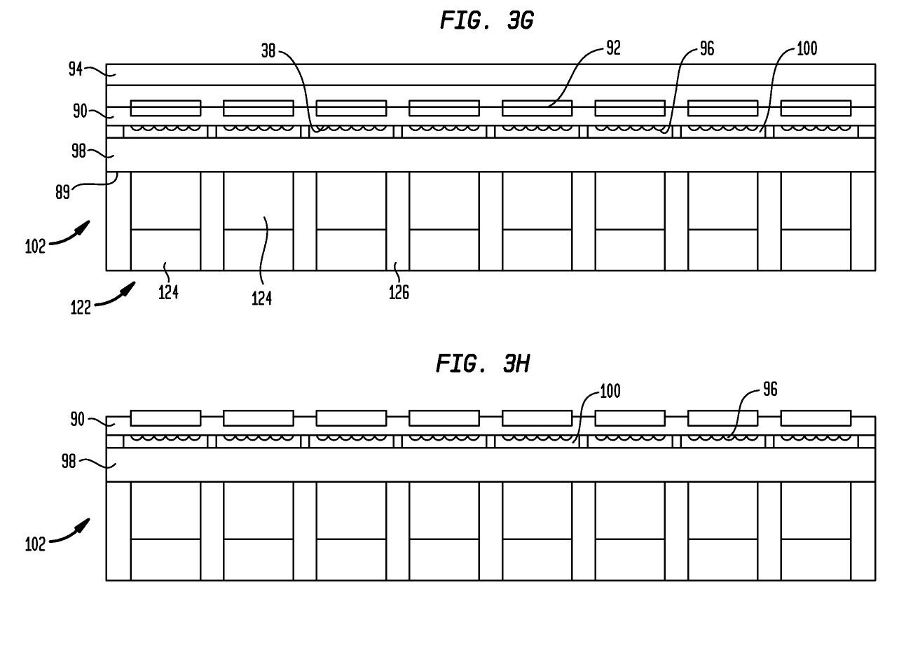

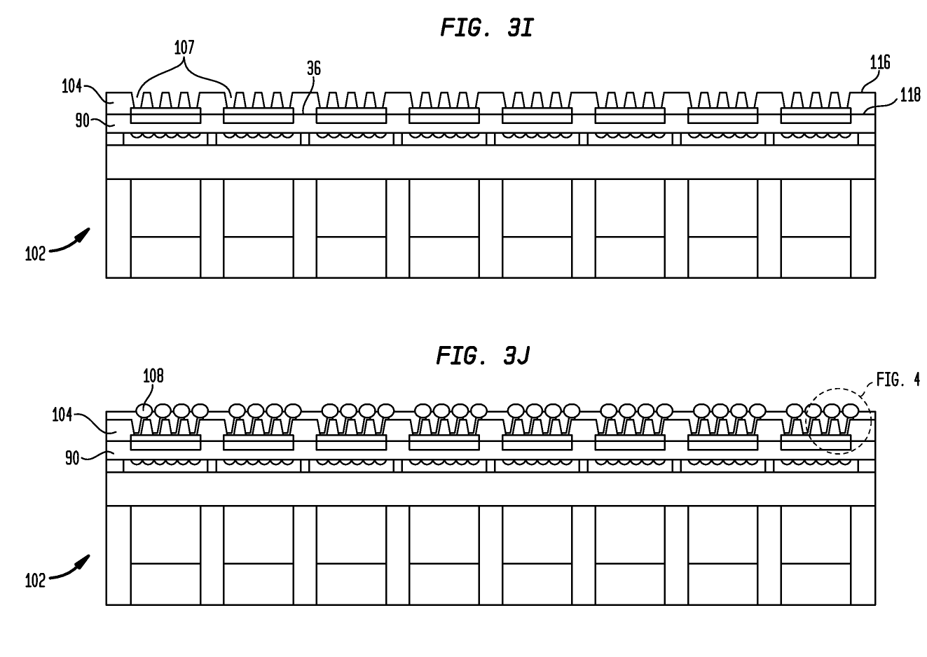

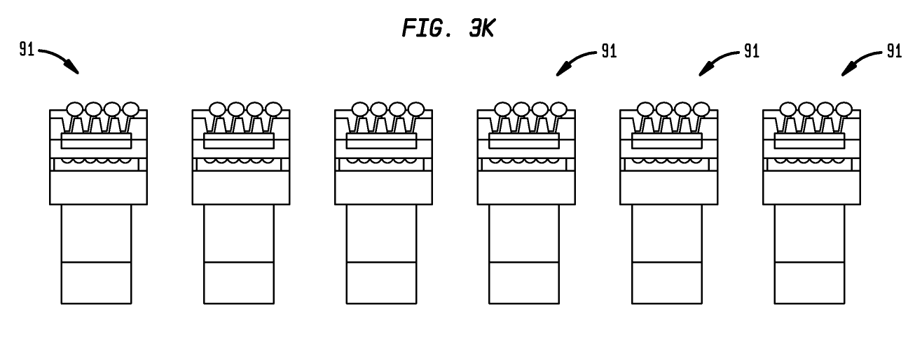

Referring to FIG. 3A, a process will now be described of packaging rear face-illuminated image sensor dies according to another embodiment of the present invention. As seen in FIG. 3A, a device wafer 90 includes active semiconductor devices including light-sensing elements 32 and other active semiconductor devices (not shown) disposed adjacent to a front face 36 of the wafer 90.

A temporary carrier, e.g., a handler wafer 94 is laminated onto the device wafer 90, as shown in FIG. 3B. It is important that during fabrication, the wafer-level assembly has sufficient mechanical integrity to withstand further assembly steps. Typically, the carrier is relatively rigid in order to support the device wafer 90 against cracking or breaking during subsequent fabrication processes. As the support wafer serves no optical function, a variety of different materials may be used. For instance, silicon, tungsten or certain metal composite materials may be used. In one embodiment, a material is used which has a coefficient of thermal expansion similar to that of the semiconductor material, e.g., silicon, which is used to form the device wafer 90.

Thereafter, the device wafer 90 is thinned from a rear face 136 of the wafer until a desired thickness 138 is reached between the front face 36 and the rear face 38, as shown in FIG. 3C. As illustrated in FIG. 3C, the thickness of the device wafer 90 is reduced by grinding, polishing, etching or the like. In one embodiment, the thickness can be reduced to between about 5 microns and 20 microns. In one embodiment, the thickness can be reduced to less than 5 microns.

Color masks (not shown), e.g., sets of color filters as described above, microlenses 96, or both can be applied on the device wafer 90 at a rear surface 38 as shown in FIG. 3D. In one embodiment, the color masks, microlenses or both can be attached to the image sensor dies using an adhesive. Preferably, an adhesive can be used which is at least partially transparent to light of wavelengths of interest to the light-sensing elements of the image sensor. Forming an array of microlenses separately and then joining the microlenses to the device wafer via lamination can reduce stresses in the device wafer and lead to greater mechanical stability. An array of micro lenses may be formed as arrays at the die or wafer level, in or on a sheet of glass or organic polymer. Techniques to form an array include printing, stamping, etching, embossing and laser ablation. An array of micro lenses can be laminated with the device wafer 90 having the same dimension as the array. Such a lamination of the device wafer 90 and the array will provide mechanical support to the device wafer 90.

Next, a lid wafer or “coverslip” wafer 98 is prepared which has standoffs 99 thereon. The standoffs 99 may take the form of a patterned adhesive layer projecting from an inwardly directed inner surface 88 of the coverslip wafer, as shown in FIG. 3E. The standoffs 99 maintain the inner surface 88 at a desired spacing from the rear surface 38 of the device wafer 90. In such manner, a cavity 100 may be formed which lies between the inner surface 88 of the coverslip wafer 98 and the rear surface 38. The coverslip wafer 98 covers the microlenses 96 once it has been laminated with the device wafer 90 as shown in FIG. 3F. The coverslip wafer 98 can help avoid dust from contacting the microlenses 96. By laminating the coverslip wafer 98 onto the rear surface 38 of the device wafer 90 in one integral unit, the major surface of the coverslip wafer 98 is maintained parallel to the rear surface 38, an arrangement which benefits the focusing of light onto the light-sensing elements 92 of the image sensors at the front surface 36 of the device wafer 90.

Thereafter, as shown in FIG. 3G, a wafer-level integrated stacked lens assembly 102 is laminated to an outer surface 89 of the coverslip wafer 98. The stacked lens assembly 102 includes a plurality of individual lens stacks 122 which are attached together at edges 126. The individual lens stacks 122 may include one or more optical elements 124 having a refractive or diffractive property, or both, or which may have a reflective, absorptive, emissive or other optical property or a combination thereof. Each lens stack is aligned with at least one image sensor 92 of the device wafer so as to cast imaging light through the rear face 38 of the wafer onto the light-sensing elements of the image sensor.

FIG. 3H illustrates a further stage of processing after the handle wafer 94 or temporary carrier is removed. Next, as seen in FIG. 3I, a dielectric layer 104 is formed overlying the front surface 36 of the device wafer 90. For example, a patterned dielectric layer of a polymeric material with an adhesive backing or simply, an adhesive dielectric layer 104 having holes 106 punched therein, can be laminated to the front surface 36 of the device wafer 90. The patterned dielectric layer 104, e.g., punched adhesive has openings or apertures, e.g., through holes 107 extending between top and bottom surfaces 116, 118 which are aligned with electrical contacts, e.g., bond pads, exposed at the front surface 36 of the dies of the wafer.

Alternatively, the dielectric layer 104 can be formed on the device wafer front surface and subsequently patterned by photolithography, or other technique such as, without limitation, laser or mechanical drilling. In one example, the dielectric layer can be deposited by a spin-on or spray-on technique.

In another example, the dielectric layer can be formed of a material such as an epoxy or an epoxy-glass substrate e.g., an FR-4 board, which is subsequently patterned. If it is desired for the dielectric layer 104 to be compliant, a compliant epoxy dielectric material can be used. If the material of the dielectric layer, e.g., FR-4 board is not sufficiently compliant, another layer, e.g., of polyimide, silicone or other material can be provided thereon to provide compliancy for traces and terminals which will be subsequently formed thereon.

In yet another embodiment, the dielectric layer can include a liquid crystal polymer (“LCP”) layer to provide compliancy. In one example, such layer can be attached to the device wafer 90 in an unpatterned condition and subsequently patterned to form through holes 107.

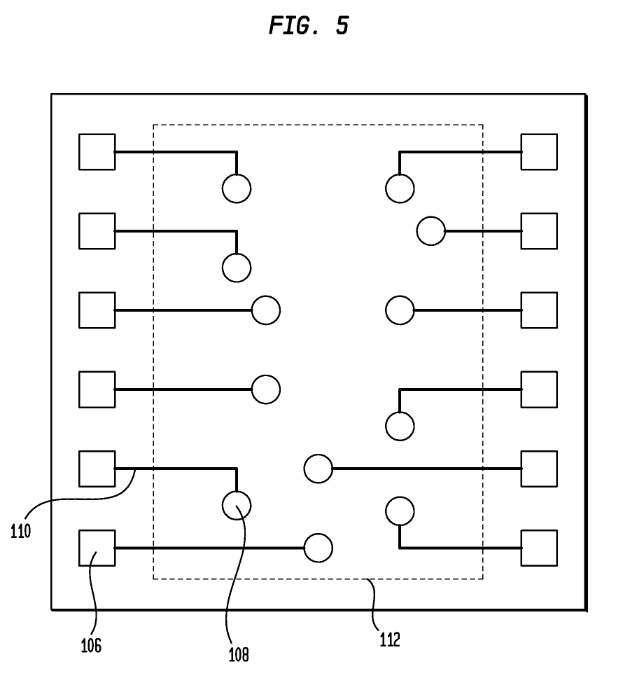

Thereafter, as seen in FIG. 3J, electrical contacts 108, exposed at the top surface 116 of the dielectric layer, may be formed which are conductively connected to the chip contacts at the front surface 36. Any manner of package contacts 108 may be formed, such as, for example, solder balls, stud bumps or a land grid array. In an embodiment of the present invention, the package contacts 108 can be distributed over the front surface of the die as illustrated in FIG. 5 such that the package contacts directly overlie at least some of the light-sensing elements of the image sensor. The assembly including the device wafer 90 may then be singulated into individual packaged chips, as shown in FIG. 3K.

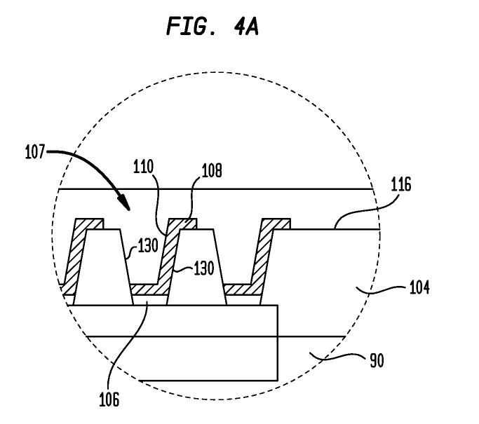

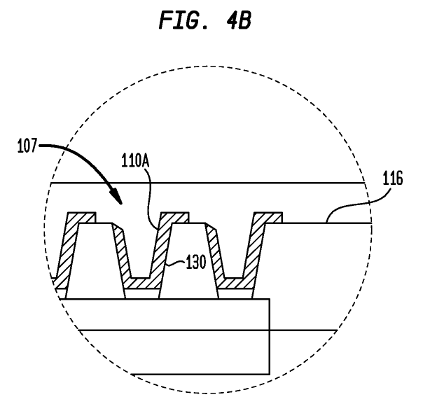

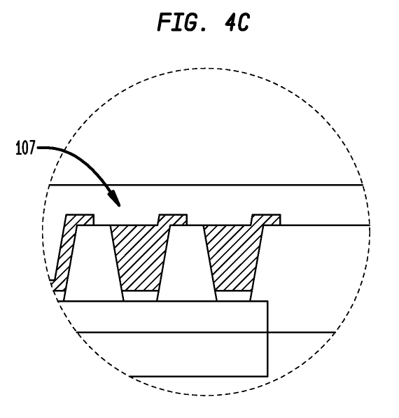

As best seen in FIG. 4A, in one embodiment, the package contacts 108 exposed at the top or outer surface 116 of the dielectric layer 104 are formed integrally with connecting leads 110 by electroplating onto exposed contacts 106 within the through holes 107. To form such leads and contacts, a seed metal layer may first be deposited onto an exposed interior walls 130 of the holes and a top surface 116 of the dielectric layer, using electroless plating or sputtering. Thereafter, a patterned photoresist mask and subsequent removal of the exposed portions of the seed layer can be used to define the locations of the desired leads. Through this process, the seed layer will be cleared from portions of the walls 130. A 3-D lithography process may be employed, such as described in commonly owned U.S. Pat. No. 5,716,759 to Badehi, the disclosure of which is incorporated by reference herein, to form seed layer patterns which cover the bottom and one wall of the openings 106. The wafer-level assembly can then be contacted with an electroplating bath to plate leads 110 and pads 108 having a desired thickness onto the seed metal layer. More information regarding this process is provided in U.S. application Ser. No. 11/789,694, filed Apr. 25, 2007, and entitled, WAFER-LEVEL FABRICATION OF LIDDED CHIPS WITH ELECTRODEPOSITED DIELECTRIC COATING, which is also hereby incorporated by reference.

Alternatively, without requiring 3-D lithography, portions of the seed metal layer which overlie the top surface 116 of the dielectric layer can be patterned and the seed layer along entire walls 130 of the through holes 107 can remain intact. In this way, the inner walls 130 of the through holes are plated to form a layer 110A which covers interior walls 130 of the holes 107, as seen in FIG. 4B. In yet another variation shown in FIG. 4C, the holes 107 can be filled with a metal.

Optionally, a conductive barrier layer may be provided adjacent to the surfaces of the dielectric layer. In one example, leads 110 can be formed which have layers starting with a layer of aluminum, then nickel, then copper (Al/Ni/Cu) and then a finish layer such as gold (Au). In another example, the leads 110 can be formed which have layers starting with a layer of titanium, then copper, then nickel, and then a finish layer such as gold (Ti/Cu/Ni/Au). In yet another example, the leads 110 can be formed which have layers starting with a layer of nickel, then palladium, then a finish layer such as gold (Ni/Pd/Au). In another example, the leads 110 can be formed which have layers starting with a layer of aluminum, then nickel, and then a finish layer such as gold (Al/Ni/Au).

In a particular embodiment of the invention, the dielectric layer 104 is not a pre-formed layer which is then laminated onto the wafer-level assembly. In such case, the dielectric 104 can be deposited using electrophoretic deposition, spin-on, spray on, roller-coating or other deposition method.

Interconnections 110, which extend upward from the front surface of the chip and laterally along a surface of layer 104 connect the peripheral bonding pads or chip contacts 106 of each chip to an area array of package contacts 108. The package contacts, 108, which may include under bump metal (UBM) pads and solder bumps or balls, can be distributed over the front surface of the chip. In one embodiment, a seed layer for forming the interconnections 110 can be formed on an exposed major surface 116 and exposed wall surfaces 130 of the holes, such as by sputtering or electrolessly depositing a metal layer thereon. Thereafter, the seed layer can be patterned by photolithography, after which the interconnections 110 can be formed, such as by electroplating one or more layers of metal thereon such as described above.

Alternatively, package contacts can be in the form of conductive masses, lands or the like. The lands may be wettable by a fusible metal such as solder, tin or a eutectic composition including a fusible metal.

The dotted line in FIG. 5 marks a boundary enclosing an area of the array 112 of light-sensing elements 92 which make up an optically active portion of the image sensor of each chip. Thus, at least some of the package contacts may directly overlie the light-sensing elements of the image sensor. Stated another way, at least some of the package contacts 108 may be disposed at positions which are aligned with the light-sensing elements in a direction normal to the top surface 116 of the dielectric layer 104. The package contacts 108 can be used to connect each packaged die 91 to a circuit panel such as an application circuit board.

The above-discussed method of forming redistributed package contacts can improve the reliability by allowing the use of larger solder balls for robust interconnection and better thermal management of the device's input output (“I/O”) system.

Further, this type of structure is advantageous because chip contacts 106 are commonly placed very closely together. For instance, the pitch of the chip contacts is usually very small, whereas the pitch of the package contacts is normally substantially greater than the pitch of the chip contacts. Substantially greater can be defined such that the ratio of the pitch of the package contacts and the pitch of the chip contacts is greater than 1.2. The ratio may be much greater than 1.2 and 2.0. Redistribution also allows for package contacts 108 to be spaced further apart than chip contacts 106 and allows the package contacts to be larger in size.

Some or all of the methods and processes described in the foregoing may be performed via chip level packaging techniques with respect to individual chips as well as wafer level packaging techniques as described above. Further, the methods recited herein are applicable to solid state image sensors as well as other types of sensors.

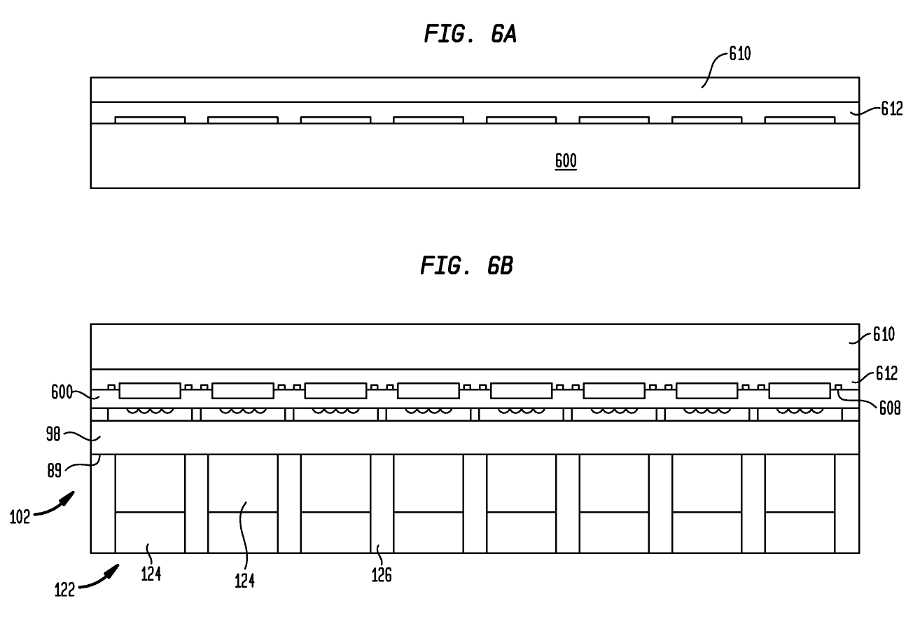

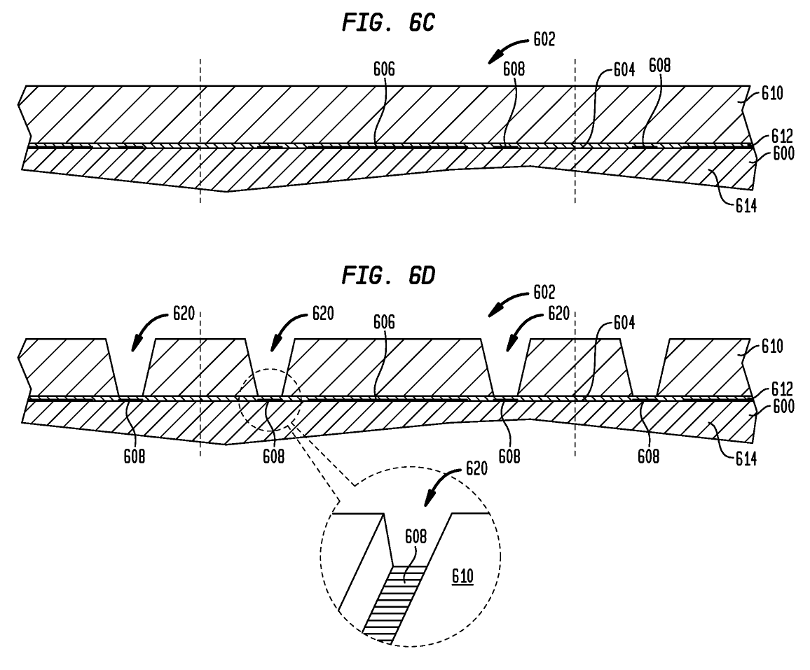

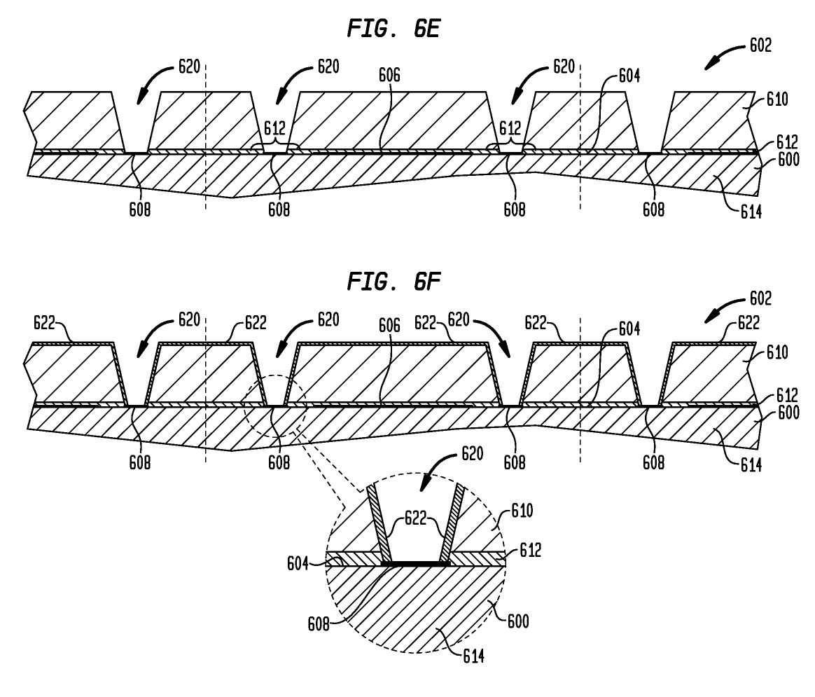

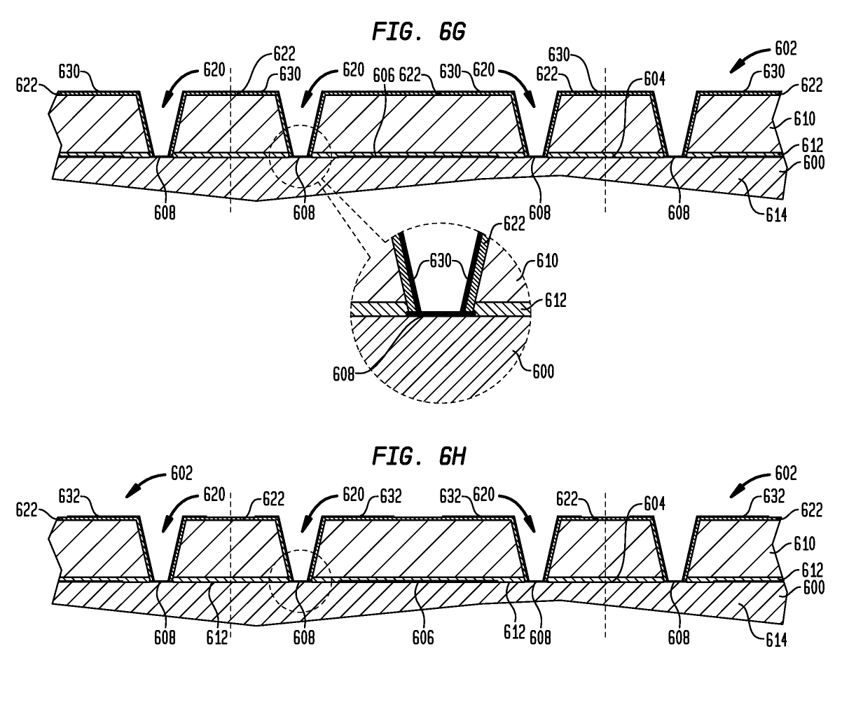

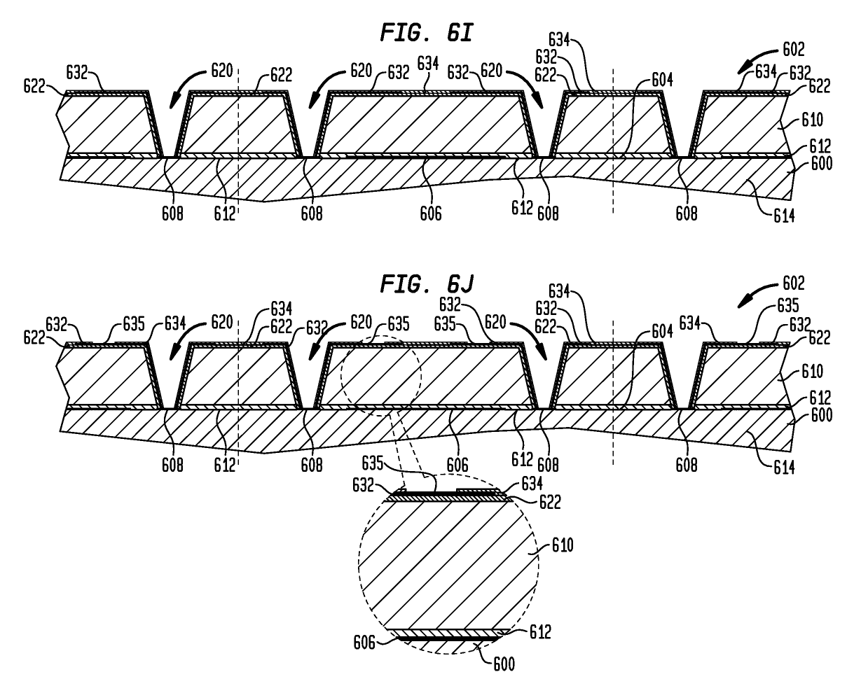

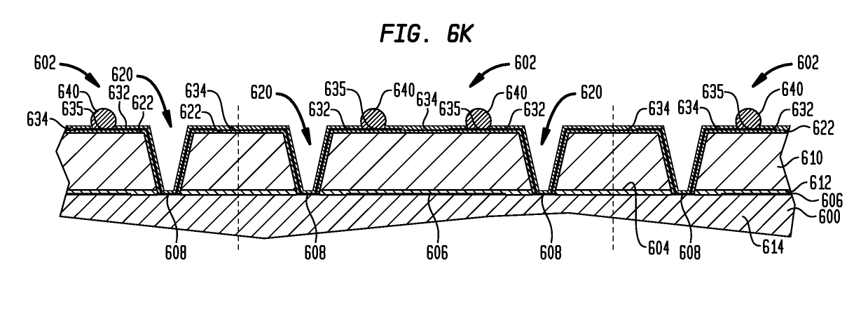

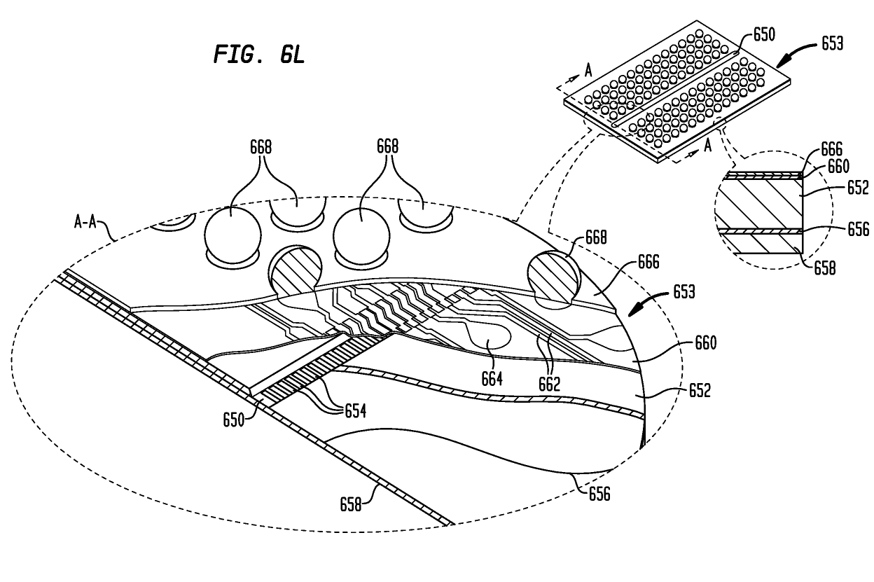

Reference is now made to FIGS. 6A-6L, which are simplified partial sectional illustrations of a method for manufacturing packaged semiconductor chips having back side, i.e., rear-face illuminated image sensors therein, in accordance with an embodiment of the present invention. Such method is similar to that described in U.S. application Ser. No. 11/604,020 filed Nov. 22, 2006, the disclosure of which is incorporated herein by reference.

Turning to FIG. 6A, there is seen part of a semiconductor wafer 600 including dies 602, each typically having an active surface 604 including electrical circuitry 106 having bond pads 608. The wafer 600 is typically silicon of thickness 730 microns. The electrical circuitry 606 may be provided by any suitable conventional technique. Alternatively, the wafer 600 may be any other suitable material, such as, for example, gallium arsenide and may be of any suitable thickness. Similar to that described above relative to FIG. 3B, a wafer-scale packaging layer 610 is attached to the wafer 600 using an adhesive 612. The adhesive can be any suitable material, and can be epoxy. The adhesive should have properties and a glass transition temperature T_{g} sufficiently high to withstand the maximum heating to be encountered during subsequent thermal processing. As seen in FIG. 6B, the adhesive 612 covers the active surfaces 604 of dies 602. Preferably, the adhesive is homogeneously applied to the packaging layer by spin bonding, as described in U.S. Pat. Nos. 5,980,663 and 6,646,289, the disclosures of which are incorporated herein by reference. Alternatively, any other suitable technique may be employed.

The thermal expansion characteristics of the packaging layer 610 can be closely matched to those of the semiconductor wafer 600. For example, if the semiconductor wafer 100 is made of silicon, which has a coefficient of thermal expansion of 2.6 μm·m⁻¹·K⁻¹ at 25° C., the packaging layer 610 can be selected so as to have a similar coefficient of thermal expansion. Furthermore, the adhesive 612 can have a coefficient of thermal expansion which is matched to the coefficients of thermal expansion of the semiconductor wafer 600 and of the packaging layer 610 or is compatible therewith. Also, in one example, when the semiconductor wafer 600 consists essentially of silicon, the packaging layer 610 may also consist essentially of silicon having sufficient conductivity to permit electrophoretic coating thereof.

After the wafer 600 is joined with the packaging layer 610, the above-described processing (FIGS. 3C-3G) can be applied thereto to form the structure shown in FIG. 6B, which is similar to the stage of processing shown in FIG. 3G, except that the packaging layer 610 is affixed to the wafer 600 in place of the carrier 94 (FIG. 3G). FIG. 6C is a partial sectional view illustrating the same structure at this stage of processing, wherein only a portion of the device wafer 600 is shown, and additional structure, e.g., lenses, filters, etc., which are attached to wafer 600 are outside the view of FIG. 6C. FIGS. 6D through 6L are also partial views illustrating stages in manufacturing packaged image sensor dies, in which the additional optical structure e.g., lenses, filters, etc., is present and attached to wafer 600 during the stages of manufacturing, although not shown in these particular drawings.

FIG. 6D shows a stage in which notches 620 are formed in the packaging layer 610 at locations which overlie bond pads 608. The notches can be formed by photolithography employing plasma etching or wet etching techniques. Each notch can be formed as a channel extending across the top surface 604 of the device wafer 600 so as to remove the material of the packaging layer 610 above multiple bond pads 608 which are arranged in a row extending across the surface 604 of the wafer. Each such channel can extend so as to uncover a few bond pads of each row of bond pads of the wafer or, each channel can uncover all bond pads in such row. Alternatively, each notch can be formed so as to uncover a single bond pad. At this stage of manufacturing, the processes used to form the notches 620 may be such that the adhesive 612 remains over the bond pads 608.

Turning to FIG. 6E, it is seen that the adhesive 612 overlying bond pads 608 and exposed by the notches 620 is removed, such as by dry etching techniques. For example, an oxygen plasma can be used to remove the adhesive 612 and expose surfaces of the bond pads 608 without damaging the bond pads.

FIG. 6F shows the formation of an electrophoretic, electrically insulative compliant layer 622 over the packaging layer 610. The compliant layer 622 can be formed so as to have a relatively low Young's modulus relative to the packaging layer 610. In addition, the compliant layer 622 may be formed with sufficient thickness so as to provide compliancy. In such way, metal features on the compliant layer, especially traces and terminals which can be subsequently formed thereon, can be moveable under the influence of externally applied loads, such as which can be applied through connections to such terminals from a printed circuit board.

In one example, the compliant layer 622 can be formed by electrophoretic deposition. Electrophoretic deposition can be utilized to form a compliant dielectric layer as a conformal coating that is deposited only onto exposed conductive and/or semiconductive surfaces of the assembly. Electrophoretically deposited coating is self-limiting in that after it reaches a certain thickness governed by parameters, e.g., voltage, concentration, etc. of its deposition, the deposition stops. Electrophoretic deposition forms a continuous and uniformly thick conformal coating on conductive and/or semiconductive exterior surfaces of the assembly. In addition, the electrophoretically deposited coating typically does not form on surfaces of existing insulating (dielectric) layers of the assembly, due to their dielectric (i.e., nonconductive) property. The electrophoretically deposited compliant layer can be formed from a cathodic epoxy deposition precursor. Alternatively, in another example, a polyurethane or acrylic deposition precursor could be used. Examples of electrophoretic coating materials that form compliant layers include Powercron 645 and Powercron 648, both commercially available from PPG of Pittsburgh, Pa., USA; Cathoguard 325, commercially available from BASF of Southfield, Mass., USA; Electrolac, commercially available from Macdermid of Waterbury, Conn., USA and Lectraseal DV494 and Lectrobase 101, both commercially available from LVH Coatings of Birmingham, UK.

Once cured, the compliant layer 622 encapsulates all exposed surfaces of the packaging layer 610. Compliant layer 622 may also provide protection to the device from alpha particles emitted by BGA solder balls.

FIG. 6G illustrates the formation of a seed metal layer 130, such as by sputtering chrome, aluminum or copper, among others or electrolessly plating such metal. The seed metal layer 630 can extend from the bond pads 608, over the compliant layer 622 and along the inclined surfaces of the packaging layer 610, defined by notches 620, onto outer, generally planar surfaces of the compliant layer 622.

As shown in FIG. 6H, metal connections 632 can be formed by patterning the seed metal layer by photolithography employing a suitable photoresist, followed by electroplating of a trace metal layer, e.g., copper or aluminum, to form traces 632 which extend from the bond pads 608 upward along the notches and onto the exposed outer (top) surface of the packaging layer 610. The metal traces 632 may be additionally plated with nickel, as by electroless techniques, in order to provide enhanced corrosion resistance.

FIG. 6I illustrates the application of a second, electrically insulative, encapsulant passivation layer 634 over the metal connections 632 and over the compliant layer 622. In one example, the encapsulant passivation layer 634 can be a photoimageable layer such as a solder mask. Such layer can be applied by spin-on, spray-on, lamination or other technique.

FIG. 6J shows patterning of the encapsulant passivation layer 634, e.g., via photolithography to define solder bump locations 635.

FIG. 6K illustrates the formation of solder bumps 640 at locations 635 on the patterned metal layer 632, at which the encapsulant passivation layer 634 is not present.

Then, similar to that described relative to FIG. 3K above, the wafer assembly can be singulated by sawing or otherwise dicing the units along scribe lines into individual units, each unit containing a packaged die.

Reference is now made to FIG. 6L, which is a simplified, partially cut away pictorial illustration of part of a packaged image sensor unit manufactured in accordance with the method of FIGS. 6A-6K. As seen in FIG. 6L, a notch 650, corresponding to notch 620 (FIGS. 6D-6K), can be formed in a packaging layer 652, corresponding to packaging layer 610 (FIGS. 6B-6K).

The notch 650 exposes a row of bond pads 654, corresponding to bond pads 608 (FIGS. 6A-6L). A layer 656 of adhesive, corresponding to layer 612 (FIGS. 6B-6K), covers a silicon layer 658, corresponding to semiconductor wafer 600, of the silicon wafer die 653 other than at notch 650, and packaging layer 652 covers the adhesive 656. An electrophoretic, electrically insulative compliant layer 660, corresponding to electrophoretic, electrically insulative compliant layer 622 (FIGS. 6E-6K), covers the packaging layer 652 and extends along inclined surfaces of notch 650, but does not cover the bond pads 654.

Patterned metal connections 662, corresponding to metal connections 632 (FIGS. 6H-6K), extend from bond pads 654 along the inclined surfaces of notch 650 and over generally planar surfaces of compliant layer 160 to solder bump locations 664, corresponding to solder bump locations 635 (FIGS. 6J-6K). An encapsulant passivation layer 666, corresponding to encapsulant passivation layer 634 (FIGS. 6I-6K), is formed over compliant layer 660 and metal connections 662 other than at locations 664. Solder bumps 668, corresponding to solder bumps 640 (FIG. 6K), are formed onto metal connections 662 at locations 664.

In a variation of the above-described embodiment, the packaging layer can be a material other than a semiconductor, e.g., silicon. For example, the packaging layer can be made of glass. In such case, the packaging layer is a dielectric material. In that case, the compliant layer can be formed by a technique other than electrophoretic coating. For example, the compliant layer can be deposited by a spin-on or spray-on technique. After forming the compliant layer by such technique, some or all of the compliant material within the notches in the packaging layer can be removed by subsequent patterning, e.g., laser or mechanical drilling.

In another example, the packaging layer can be formed of a material such as an epoxy or an epoxy-glass substrate e.g., an FR-4 board, which is subsequently patterned. On such epoxy layer, if it is not sufficiently compliant, another layer, e.g., polyimide, silicone or other material can be provided thereon to provide compliancy for traces and terminals which are formed thereon.

In yet another embodiment, the packaging layer can include a liquid crystal polymer (“LCP”) layer to provide compliancy. In one example, such layer can be attached to the device wafer 600 in unpatterned condition and subsequently patterned to form notches, after which traces and terminals can be formed thereon. In this case, processing steps similar to that described above with respect to FIGS. 6D-6L can be performed, except that the processing referred to in FIG. 6F is not performed.

In one variation of the above-described embodiments, conductive elements, e.g., traces, pads, etc., between the bond pads on the wafer and the terminals at a face of the package can be formed by a different technique similar to that used in the fabrication of printed circuit boards. For example, a dielectric material, e.g., an epoxy-glass composite such as an FR-4 layer can be used as the packaging layer which can then be roughened by a pre-treatment process, after which a continuous metal layer can be formed thereon such as by electroplating. Thereafter, the continuous metal layer can be subtractively patterned by photolithography to form the conductive elements.

The above-described embodiments have shown packaged image sensors which have solder bump terminals 30 (FIG. 2A) exposed at a face of the package for interconnection. The solder bump terminals are exposed above the surface of a solder mask layer 28, e.g., a “solder mask face”. It is also possible for packages to have lands exposed at a face thereof, such as for a land grid array (“LGA”) style interface. In such case, a solder mask layer may not be present at the face of the package.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A solid state image sensor, comprising:
a microelectronic element having a front face and a rear face remote from the front face, the rear face including a surface a first distance from the front surface in a direction normal to the front surface;
a plurality of light sensing elements disposed adjacent to the front face and aligned with the surface of the rear face so as to receive light through that surface;
packaging structure attached to the front surface of the microelectronic element, the packaging structure including at least one compliant layer; and
electrically conductive package contacts disposed on the compliant layer and overlying the front face and the light sensing elements so as to be movable with respect to the chip contacts under external loads applied to the package contacts.

2. The image sensor as claimed in claim 1, further comprising an at least partially transparent lid disposed adjacent to the rear face, the lid overlying the recess.

3. The image sensor as claimed in claim 1, further comprising electrical contacts exposed at the front face, the contacts conductively connected to the light sensing elements.

4. A solid state image sensor, comprising:
a microelectronic element having a front face, a plurality of chip contacts at the front face, a rear face remote from the front face, and a plurality of light sensing elements disposed adjacent to the front face and conductively connected to the chip contacts, the light sensing elements being arranged to receive light through the rear face;
packaging structure attached to the front surface of the microelectronic element, the packaging structure including at least one compliant layer;
electrically conductive package contacts disposed on the compliant layer and overlying the front face and the light sensing elements so as to be movable with respect to the chip contacts under external loads applied to the package contacts; and
conductors extending within openings in the packaging layer from the chip contacts to the package contacts.

5. The image sensor as claimed in claim 4, wherein the light sensing elements include active semiconductor devices disposed adjacent to the front face.

6. The image sensor as claimed in claim 5, wherein the conductors include vertical interconnects in conductive communication with the active semiconductor devices and the package contacts.

7. The image sensor as claimed in claim 4, wherein the chip contacts are exposed within openings, the image sensor further comprising leads extending along interior surfaces of the openings connecting the chip contacts to the package contacts, each lead covering less than an entire exposed interior surface of each opening.

8. The image sensor as claimed in claim 4, wherein each lead extends along only a portion of an interior wall of each opening.

9. The image sensor as claimed in claim 8, wherein a second portion of the wall of the vertical interconnect remote from the first portion remains uncovered by the lead.

10. The image sensor as claimed in claim 4, wherein the light sensing elements are disposed in a first region of the microelectronic element and the chip contacts are disposed in a second region laterally adjacent to the first region, wherein the leads extend from the chip contacts to locations overlying the first region.

11. The image sensor as claimed in claim 10, wherein the second region is disposed between the first region and an edge of the microelectronic element.

12. The image sensor as claimed in claim 4, wherein the package contacts are spaced farther apart than the chip contacts, and wherein the chip contacts are disposed in at least a first direction along the front surface, the chip contacts having a first pitch in the first direction and the package contacts having a second pitch in the first direction, the second pitch being substantially greater than the first pitch.

13. The image sensor as claimed in claim 4, wherein the package contacts include conductive masses.

14. The image sensor as claimed in claim 4, wherein the package contacts include lands.

15. The image sensor as claimed in claim 14, wherein the lands are wettable by a fusible metal.

16. The image sensor as claimed in claim 4, further comprising a cover slip adjacent to the rear face.

17. The image sensor as claimed in claim 4, further comprising an integrated stack lens disposed adjacent to the rear face.

18. The method as claimed in claim 4, further comprising a circuit panel having terminals bonded to the package contacts, wherein the package contacts are subject to the external loads applied from the terminals of the circuit panel.

19. A method of packaging a microelectronic image sensor comprising:
(a) recessing portions of a rear surface of a device wafer, the portions being aligned with a plurality of light sensing elements adjacent to a front surface of the device wafer;
(b) forming package contacts conductively interconnected with chip contacts exposed at the front surface;
(c) assembling the device wafer with a light transmissive structure overlying the rear surface;
(d) severing the device wafer into individual packaged chips, each containing light sensing elements arranged to receive light through at least one of the recessed portions; and
(e) bonding the package contacts to terminals of a circuit panel, wherein the package contacts are subject to the external loads applied from the terminals of the circuit panel.

20. The method as claimed in claim 19, further comprising forming a plurality of microlenses within each recessed portion, each microlens aligned with one or more of the light sensing elements.

21. The method as claimed in claim 20, wherein step (c) includes assembling the device wafer with a lid wafer.

22. The method as claimed in claim 21, wherein step (d) includes severing the device wafer and the lid wafer.

23. The method as claimed in claim 19, wherein the package contacts overlie packaging structure attached to the front surface of the device wafer including at least one compliant layer, the package contacts being disposed on the compliant layer so as to be movable with respect to the chip contacts under external loads applied to the package contacts.
